(19) United States
(12) Patent Application Publication
(10) Pub. No.: US 2008/0013058 A1
(43) Pub. Date: Jan. 17, 2008

(54) Pneumatic Spring Apparatus, Vibration-Proof Apparatus, Stage Apparatus and Exposure Apparatus

(75) Inventor: Yosuke Tatsuzaki, Saitamaken (JP)

Correspondence Address: STAAS & HALSEY LLP, SUITE 700, 1201 NEW YORK AVENUE, N.W., WASHINGTON, DC, 20005, US

(73) Assignee: NIKON CORPORATION, Chiyoda-ku, Tokyo (JP)

(21) Appl. No.: 10/591,670

(22) PCT Filed: Mar. 1, 2005
(86) PCT No.: PCT/JP05/03381

§ 371 Date: Jun. 15, 2007

(30) Foreign Application Priority Data
Mar. 1, 2004 (JP) 2004-056195

(51) Int. Cl. F16F 15/023; G03B 27/42; H01L 21/30

(52) U.S. Cl. 355/53; 267/113; 267/137

(57) ABSTRACT

A high performance pneumatic spring apparatus is provided without increasing the sizes of the apparatus. The pneumatic spring apparatuses KB1-KB4 are provided with gas chambers AR filled with a gas at a prescribed pressure. The gas chamber AR is provided with an adjustment apparatus SW for adjusting a temperature change due to the capacity change of the gas chamber AR.

### FIELD OF THE INVENTION

The present invention relates to a pneumatic spring apparatus and an anti-vibration apparatus for supporting an object with a gas pressure; and also to a stage apparatus and an exposure apparatus that are provided with the anti-vibration apparatus.

The subject application claims the priority of Japanese Patent Application No. 2004-56195 filed on Mar. 1, 2004, the disclosure of which is incorporated herein by reference.

### BACKGROUND OF THE INVENTION

Conventionally, in a lithography process, one of the semiconductor device manufacturing processes, a variety of exposure apparatuses have been used to transfer circuit patterns formed on a mask or reticle (hereinafter referred to as a “reticle”) to a substrate, such as a wafer, a glass plate or the like, coated with a resist (photosensitive agent).

In an effort to meet the recent trend of high integration of integrated circuits and the resultant miniaturization of a minimum line width (device rule), a reduction projection exposure apparatus for reduction-transferring the patterns of a reticle to a wafer through the use of a projection optical system is being extensively used as an exposure apparatus for a semiconductor device.

Examples of the reduction projection exposure apparatus known in the art include a step-and-repeat manner stationary exposure type reduction projection exposure apparatus (the so-called “stepper”) wherein the patterns of a reticle are transferred to a plurality of shot regions (exposure regions) on a wafer one after another; and as an improvement of the stepper, a step-and-scan manner scan exposure type exposure apparatus (the so-called “scanning stepper”) as disclosed in patent reference 1, wherein a reticle and a wafer are synchronously displaced in a one-dimensional direction to transfer reticle patterns to individual shot regions on the wafer.

In the reduction projection exposure apparatuses noted above, a widely used stage apparatus is of the type wherein a base plate serving as an apparatus datum level is first installed on a floor surface, and an anti-vibration table is provided on the base plate for insulation of floor vibration, and main body column is then mounted so as to support a reticle stage, a wafer stage, a projection optical system (projection lens) and the like. Employed as the anti-vibration table in the state-of-the-art stage apparatuses is an active anti-vibration table that includes an air mount (pneumatic spring apparatus) capable of controlling an internal pressure and an actuator (thrust force imparting device) such as a voice coil motor or the like. The active anti-vibration table is adapted to control the vibration of a main body column by controlling the thrust force of the voice coil motor or the like based on, e.g., the measurement data of six accelerometers attached to the main body column (main frame).

Patent Reference 1: Japanese Patent Laid-open Application No. H8-166043.

Performance of a pneumatic spring depends on the vibration transmission rate thereof. The smaller (lower) the rigidity of the pneumatic spring, i.e., spring constant of the pneumatic spring, becomes, the better the vibration is suppressed. In view of the fact that the spring constant is inversely proportional to the volume of the pneumatic spring, an increased volume is required to obtain a pneumatic spring of low rigidity.

With this in mind, one may think of either increasing the volume of an internal space in an air mount or additionally attaching an air tank to the air mount. However, either of these alternatives may lead to an increase in apparatus size. Restriction in footprint (installation area) usually imposed on an apparatus makes it difficult for the air mount to have an increased volume.

A further alternative method of reducing the spring constant of the pneumatic spring is to change an effective pressure receiving area depending on the stroke change of the pneumatic spring. If a shape of a diaphragm or the like is designed through the application of this method, it may become possible to give a negative rigidity to the pneumatic spring, thereby reducing the spring constant.

The spring constant can be divided into a dynamic spring constant and a static spring constant. The static spring constant equal to or smaller than zero may cause a problem of instability as a spring.

Each of the dynamic spring constant and the static spring constant is mainly represented by the sum of a spring constant component attributable to the gaseous substance per se and a spring constant component attributable to the changing rate of an effective pressure receiving area. The spring constant component attributable to the gaseous substance per se is in proportion to a polytropic index. In an air spring, the polytropic index of the dynamic spring constant is equal to 1.4 and the polytropic index of the static spring constant is equal to 1.0. For this reason, it is impossible to make zero the dynamic spring constant even if the spring constant component attributable to the changing rate of an effective pressure receiving area is adjusted to render the static spring constant zero. This means that there was a limit in reducing the dynamic spring constant.

### SUMMARY OF THE INVENTION

In view of the foregoing and other problems, it is an object of the present invention to provide a pneumatic spring apparatus and an anti-vibration apparatus that exhibit high performance without increasing the apparatus sizes, and a stage apparatus and an exposure apparatus that show excellent anti-vibration performance.

In order to achieve the above object, the following configurations are employed in the present invention.

A pneumatic spring apparatus of the present invention is the one having a gas chamber filled with a gaseous substance of a predetermined pressure, and includes a regulating device provided in the gas chamber for regulating a temperature change produced according to a volume change of the gas chamber.

In the pneumatic spring apparatus of the present invention, therefore, it is possible for the regulating device to suppress the temperature change in the gas chamber before there occurs a temperature change of a gaseous substance by the change of internal volume of the gas chamber caused in response to the spring displacement. In case where the temperature change is negligibly small as compared to the conventional art, the polytropic index of the dynamic spring constant can be reduced from 1.4 to about 1.0 in case of the air for example. Thus, in the present invention, the spring constant (natural vibration frequency) becomes small such that the vibration transmission rate is improved drastically, thereby enhancing the performance of the pneumatic spring.

An anti-vibration apparatus of the present invention includes: a support device for supporting a target anti-vibration object with a gaseous substance of a predetermined pressure; and a drive device for driving the target anti-vibration object, wherein the support device is the pneumatic spring apparatus recited in any one of claims 1 through 7.

In the anti-vibration apparatus of the present invention, therefore, the vibration transmission rate of the support device becomes small such that the transmission of the vibration to the target anti-vibration object is suppressed, thereby effectively damping the vibration.

A stage apparatus of the present invention is the one in which a movable body is moved on a surface plate, wherein the surface plate is supported by the anti-vibration apparatus defined in claim 8.

Therefore, in the stage apparatus of the present invention, operating the support device and the drive device in response to the movement of the movable body makes it possible to prevent uneven load from being applied to the surface plate while avoiding the transmission of the vibration, and to effectively damp the vibration generated by the movement of the movable body.

An exposure apparatus of the present invention is the one for exposing patterns of a mask held on a mask stage to a photosensitive substrate held on a substrate stage through a projection optical system, wherein at least one of the mask stage, the projection optical system and the substrate stage is supported by the anti-vibration apparatus set forth above.

An anti-vibration method of the present invention includes the steps of: filling a gaseous substance of a predetermined pressure into a gas chamber; and regulating a temperature change produced according to a volume change of the gas chamber.

Therefore, in the exposure apparatus of the present invention, operating the support device and the drive device in response to the movement of the mask stage and/or the substrate stage makes it possible to prevent uneven load from being applied to the surface plates for supporting the respective stages and the surface plate for supporting the projection optical system while avoiding the transmission of the vibration, and to effectively damp the vibration generated by the movement of the mask stage and/or the substrate stage.

In accordance with the present invention, it is possible to provide a pneumatic spring of high performance by reducing a spring constant without increasing the size of the apparatus. Furthermore, the present invention enables effective damping of the vibration generated in a target anti-vibration object, and thus the pattern transfer accuracy can be enhanced when applied to an exposure apparatus.

### BRIEF DESCRIPTION OF THE DRAWINGS

FIG. 1 is a view of a first embodiment of the present invention, showing a schematic configuration of a pneumatic spring apparatus wherein an air chamber is filled with steel wool.

FIG. 2 is a view of a second embodiment of the present invention, showing a schematic configuration of a pneumatic spring apparatus wherein an air chamber is filled with a gaseous substance.

FIG. 3 is a view of a fourth embodiment of the present invention, showing a schematic configuration of a pneumatic spring apparatus wherein a fan is installed in an air chamber.

FIG. 4 is a view of a fifth embodiment of the present invention, showing a schematic configuration of a pneumatic spring apparatus wherein an air chamber is filled with steel wool.

FIG. 5 is a view illustrating a major part of a pneumatic spring apparatus.

FIG. 6 is a view showing a schematic configuration of an embodiment of an exposure apparatus provided with a stage apparatus of the present invention.

FIG. 7 is a schematic perspective view of the stage apparatus.

FIG. 8 is a partially enlarged view showing a surface plate supported by an anti-vibration unit and provided with a corner cube placed thereupon.

FIG. 9 is a schematic perspective view showing one embodiment of a stage apparatus provided with a mask stage.

FIG. 10 is a flowchart illustrating one example of a semiconductor device manufacturing process.

### DESCRIPTION OF REFERENCE CHARACTERS

AR air chamber (gas chamber), EX exposure apparatus, F fan (stirring device), G gaseous substance (regulating device, gas), KB1-KB4 pneumatic spring apparatus, M mask (reticle), MST mask stage (reticle stage), P photosensitive substrate, PL projection optical system, PST substrate stage (movable body), SW steel wool (fiber-shaped steel, regulating device), 2 stage apparatus, 4 substrate surface plate (target anti-vibration object, surface plate), 13 anti-vibration unit (anti-vibration apparatus), 72 air mount (support device), 73 voice coil motor (drive device).

### DETAILED DESCRIPTION OF THE PREFERRED EMBODIMENTS

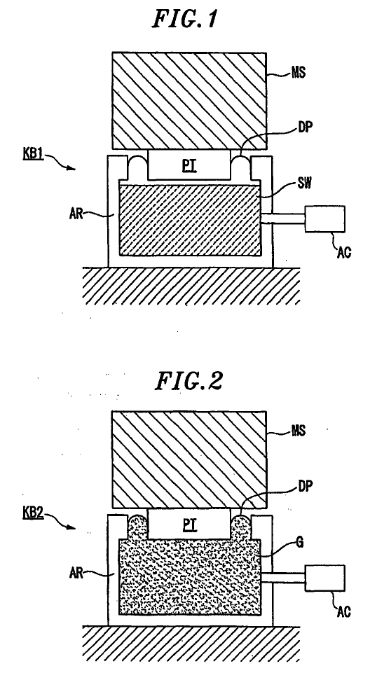

Hereinafter, embodiments of a pneumatic spring apparatus, an anti-vibration apparatus, a stage apparatus and an exposure apparatus of the present invention are to be described with reference to FIGS. 1 through 10.

### First Embodiment

Description will be first given to a pneumatic spring apparatus.

FIG. 1 is a view showing a schematic configuration of a first embodiment of the pneumatic spring apparatus in accordance with the present invention.

The pneumatic spring apparatus KB1 shown in the figure is filled with a predetermined pressure of an air (gaseous substance), thereby supporting a mass MS on the spring by (the pressure of) the air in an up-down direction in the figure (hereinafter referred to as a “Z-direction”). The pneumatic spring apparatus KB1 includes an air chamber (gas chamber) AR, a cylindrical piston PT making contact with the mass MS, a diaphragm DP covering the air chamber AR and supporting the piston PT in a manner that the piston PT freely moves in the Z-direction and a pneumatic pressure regulating device AC for controlling an air supply to the air chamber AR and thus regulating the pneumatic pressure.

Steel wool (fiber-shaped steel) SW is filled in the air chamber AR, as a regulating device for regulating the temperature change caused by the volume change of the air chamber AR.

The force W acting on the pneumatic spring KB1 is represented by the following equation:

W=P×A (1),

where the A is an effective pressure receiving area and the P is an internal pressure (gauge pressure).

The dynamic spring constant Kd of the pneumatic spring KB1 at the time when the steel wool SW is not filled is generally represented by the following equation:

$$\begin{matrix}Kd = d W / d X \\ = A \times ( d P / d X ) \\ = γ \times ( P + P a ) \times {A}^{2} / V\end{matrix} , \qquad ( 2 )$$

where the Pa is an atmospheric pressure, the X is a compressional curvature of the pneumatic spring KB1, the V is an internal volume of the air chamber AR, and the γ is a polytropic index. Although the rigidity of the diaphragm DP is added in practice, this is omitted in the description offered below.

In equation (2), the polytropic index γ for the dynamic spring becomes 1.4.

In this embodiment, the air chamber AR is filled with the steel wool SW having an increased surface area and a specific heat (or heat transfer rate) greater than that of the air. Thus the temperature change according to the change of an internal volume caused by the displacement of the mass MS is suppressed by the instantaneous heat exchange with the steel wool SW. For example, the steel wool SW absorbs the heat generated by the compression of the air in the air chamber AR and on the contrary, the steel wool SW emits the heat at the time of expansion of the air, thereby suppressing (regulating) the temperature change of the air.

In general, the difference in the polytropic index between the dynamic spring and the static spring for a pneumatic spring apparatus is due to the fact that the change of internal volume of the air chamber AR in the natural vibration frequency zone of the pneumatic spring apparatus is substantially an adiabatic change. In this embodiment, however, the heat transfer occurs at a high speed between the air and the steel wool SW even in the natural vibration frequency zone. This makes it possible to suppress the air temperature change in the air chamber AR, resulting in a nearly isothermal change. Accordingly, it is possible to suppress a pressure change caused by the temperature change (heat). Thus the polytropic index γ for the dynamic spring constant Kd becomes nearly 1.0 if the temperature change is negligibly small as compared to the case of no steel wool SW being filled.

In this respect, the dynamic spring constant Kd0 at the time when the steel wool SW is not filled is represented by the following equation (3), and the dynamic spring constant Kd1 at the time when the steel wool SW is filled is represented by the following equation (4):

Kd0=1.4×(P+Pa)×A²/V (3); and

Kd1=1.0×(P+Pa)×A²/(V−Vs) (4),

where the Vs is a volume of the steel wool SW.

If the volume Vs of the steel wool SW is negligibly small as compared to the volume of the air chamber AR, it becomes that V−Vs□V, and the following equation is derived from the equations (3) and (4):

Kd1=(1/1.4)×Kd0 (5)

As is shown in the equation (5), the dynamic spring constant can be decreased by filling the steel wool SW into the air chamber AR.

Thus, in this embodiment, by a simple structure in which the steel wool SW is filled in the air chamber AR, the spring constant can be reduced without enlarging the volume of the air chamber AR, thereby providing a high performance pneumatic spring KB1.

Also, the configuration of the embodiment described above is of the form that the fiber-shaped steel wool SW having a specific heat (or heat transfer rate) greater than that of the air is filled in the air chamber AR, but is not limited thereto. The same operation and effect as in the foregoing embodiment can be obtained by using other solid or liquid materials having a shape of increased specific surface area such as a plate shape, a wire shape (mesh shape), a particulate shape (powder shape), a porous shape, a bubble shape or the combination of these shapes. Concrete examples of the filling materials include, e.g., sintered metal and sponge (interconnected porous structure).

### Second Embodiment

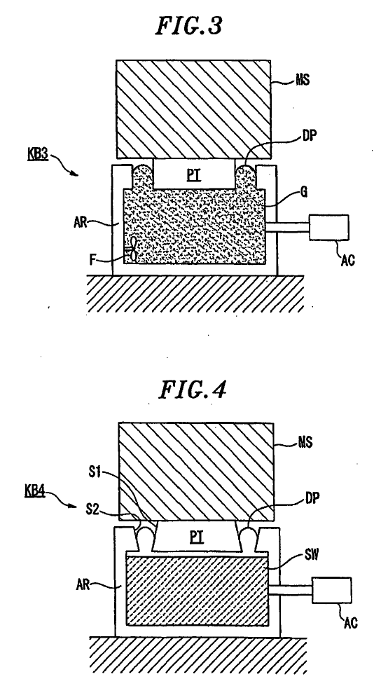

Next, description will be given to another embodiment of the pneumatic spring apparatus with reference to FIG. 2.

In this figure, like components as those of the first embodiment shown in FIG. 1 will be designated by like reference characters and the description thereof will be omitted.

In the pneumatic spring apparatus KB2 shown in FIG. 2, a gaseous substance G having a small specific heat ratio is filled in the air chamber AR in place of the air and serves as a regulating device for regulating the temperature change caused by the volume change of the air chamber AR. Gaseous substances having a specific heat ratio smaller than that of the air, such as diethyl ether, acetylene, bromine, carbon dioxide, methane and the like, are used as the filling gaseous substance G.

The polytropic index γ of 1.4 for the dynamic spring set forth above is in the case of the air. However, if the above-mentioned gaseous substances having small specific heat ratios are used, the polytropic index becomes smaller than for the case of using the air (γ=1.4). Specifically, γ=1.02 in the case of diethyl ether; γ=1.26 in the case of acetylene; γ=1.29 in the case of bromine; γ=1.3 in the case of carbon dioxide; and γ=1.31 in the case of methane. As a consequence, the spring constant can be reduced as in the first embodiment, thereby providing a high performance pneumatic spring.

Furthermore, in selecting the gaseous substances G filled in the air chamber AR, consideration needs to be given to other properties than the specific heat ratio, such as liquefaction resistance under a pressurized condition at an ordinary temperature, nontoxicity, flame retardancy or the like. In view of these properties, carbon dioxide is one of the most practical gaseous substances.

### Third Embodiment

Next, description will be given to another embodiment of the pneumatic spring apparatus.

Although a gaseous substance is filled in the air chamber AR in the embodiment described above, a gas where saturated vapor and liquid are mixed is filled in a gas liquid mixed phase condition in this embodiment.

In the gas liquid mixed phase condition, the internal pressure of the air chamber AR is ideally determined by the temperature alone, and the change in the internal volume does not give rise to a change in the pressure.

Accordingly, in the pneumatic spring apparatus having the gas in a gas liquid mixed phase condition, the polytropic index γ becomes zero both in the dynamic spring and the static spring. This makes it possible to reduce the spring constant, providing a high performance pneumatic spring. Examples of the material used in the gas liquid mixed phase condition include butane and propane.

### Fourth Embodiment

Next, description will be given to another embodiment of the pneumatic spring apparatus with reference to FIG. 3.

In this figure, like components as those of the second embodiment shown in FIG. 2 will be designated by like reference characters and the description thereof will be omitted.

The pneumatic spring apparatus KB3 illustrated in FIG. 3 is provided with a fan (stirrer) F for stirring and thus mixing up the gaseous substance G in the air chamber AR.

In this configuration, the gaseous substance G in the air chamber AR is mixed up by the operation of the fan F, thereby increasing the heat transfer rate between the inner wall of the air chamber AR and the gaseous substance G, thus suppressing the temperature change of the gaseous substance G at the time of volume change of the air chamber AR. Therefore, in this embodiment, it is possible to reduce the polytropic index and the spring constant of the dynamic spring for the pneumatic spring apparatus KB3, thereby providing a high performance pneumatic spring.

The fan F serving as a stirrer may be applied not only to the second embodiment but also to the first embodiment illustrated in FIG. 1 in which the steel wool SW is filled in the air chamber and the third embodiment in which the air chamber is filled with the gas in a gas liquid mixed phase condition. The heat transfer rate between the inner wall of the air chamber and the gaseous substance G may be increased not only by stirring the gaseous substance G but also by enlarging the surface area of the inner wall of the air chamber through the formation of irregularities on the inner wall of the air chamber is effective in that the heat exchange is promoted to thereby suppress the temperature change of the gaseous substance G.

### Fifth Embodiment

Next, description will be given to another embodiment of the pneumatic spring apparatus with reference to FIG. 4.

In this figure, like components as those of the first embodiment shown in FIG. 1 will be designated by like reference characters and the description thereof will be omitted.

In this embodiment, the dynamic spring constant is reduced by changing the effective pressure receiving area of the pneumatic spring apparatus depending on the stroke change.

Hereinafter, description is provided in more detail.

In the pneumatic spring apparatus KB4 shown in FIG. 4, the piston PT is configured in a taper-shape where its diameter is gradually decreased toward the top, and one end of the diaphragm DP is coupled to this slanted surface S1. The engaging portion of the air chamber AR coupled to (the other end of) the diaphragm DP is formed of a slanted surface S2 whose diameter is gradually increased toward the top.

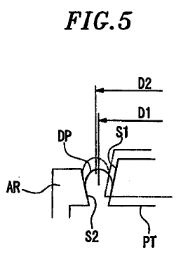

In the configuration set forth in the above, if the piston PT is displaced, for example, upwardly as depicted in FIG. 5, the diaphragm DP is moved outwardly along the slanted surfaces S1 and S2 (indicated by a dashed double-dotted line). That is, the effective diameter of the piston PT is changed from D1 to D2 (D2>D1). By doing so, the effective pressure receiving area of the pneumatic spring apparatus is increased from πD1²/4 up to πD2²/4.

Here, if the effective pressure receiving area of the pneumatic spring apparatus KB4 shown in FIG. 4 is changed, the spring constant K is represented by the following equation:

$$\begin{matrix}K = d W / d X \\ = A \times ( d P / d X ) + P \times ( d A / d X ) \\ = γ \times ( P + P a ) \times {A}^{2} / ( V - Vs ) + P \times ( d A / d X )\end{matrix} \qquad ( 6 )$$

In the equation (6), since the compressional curvature X becomes smaller as the effective pressure receiving area A gets bigger, the changing rate (dA/dX) of the effective pressure receiving area becomes a negative value.

Since the condition under which the pneumatic spring apparatus KB4 to be kept statically stable is that the static spring constant K (Ks) is greater than zero (γ=1.0), the changing rate of the effective pressure receiving area is set so as to minimize the static spring constant Ks while satisfying the above condition.

At this time, the dynamic spring constant Kd is also represented by:

Kd=γ×(P+Pa)×A²/(V−Vs)+P×(dA/dX)

Since the polytropic index γ is such that γ□1.0 as noted above, the result is Ks□Kd.

Accordingly, in this embodiment, if the changing rate (dA/dX ) of the effective pressure receiving area is regulated so as to minimize the static spring constant Ks while securing stability, it is also possible to set the dynamic spring constant Kd to be an extremely low, almost identical value.

As a result of this, the natural vibration frequency of the pneumatic spring apparatus KB4 becomes extremely small, thereby drastically improving (reducing) the vibration transmission rate critical for functioning the pneumatic spring apparatus.

### Sixth Embodiment

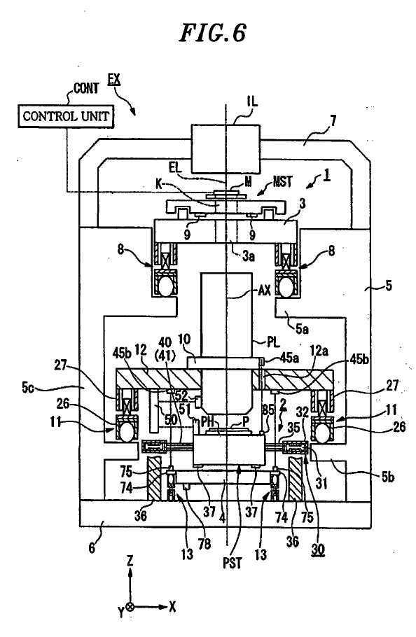

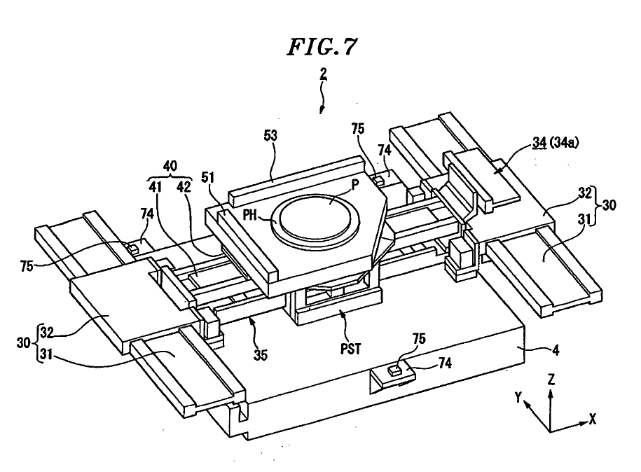

Next, an example of an exposure apparatus provided with the aforementioned pneumatic spring apparatus as a part of an anti-vibration apparatus will be described with reference to FIGS. 6 through 9.

FIG. 6 is a schematic configuration showing one embodiment of an exposure apparatus in which a stage apparatus having the pneumatic spring apparatus of the present invention is applied to a substrate stage. Here, the exposure apparatus EX of this embodiment is a so-called scanning stepper by which the patterns formed on a mask M are transferred to a photosensitive substrate P through a projection optical system PL while synchronously moving the mask M and the photosensitive substrate P. In the following description, the direction coinciding with the optical axis AX of the projection optical system PL will be referred to as a Z-axis direction which in turn serves as a first direction; the synchronous movement direction (scanning direction) in a plane perpendicular to the Z-axis direction will be referred to as a Y-axis direction; and the direction (non-scanning direction) perpendicular to the Z-axis direction and the Y-axis direction will be referred to as an X-axis direction. Further, the “photosensitive substrate” used herein includes a semiconductor wafer on which a resist is coated, and the “mask” includes a reticle having device patterns which are to be reduce-projected on the photosensitive substrate.

Referring to FIG. 6, the exposure apparatus EX includes an illumination optical system IL for illuminating a rectangular (or arc-shaped) illumination region on the mask (reticle) M by means of an exposure light EL issued from a light source not shown in the drawing; a stage apparatus 1 having a mask stage (reticle stage) MST for holding and moving the mask (reticle) M and a mask surface plate 3 for supporting the mask stage MST; a projection optical system PL for projecting the exposure light EL penetrating the mask (reticle) M onto the photosensitive substrate P; a stage apparatus 2 according to the present invention having a substrate stage PST for holding and moving the photosensitive substrate P and a substrate surface plate 4 for supporting the substrate stage PST; a reaction frame 5 for supporting the illumination optical system IL, the stage apparatus 1 and the projection optical system PL; and a control unit CONT for generally controlling the operation of the exposure apparatus EX.

The reaction frame 5 is installed on a base plate 6 horizontally mounted on a floor surface. Further, at the top and the bottom side of the reaction frame 5, inwardly-protruding step portions 5a and 5b are formed, respectively.

Also, the projection optical system PL is, via a flange portion 10, fixed to a lens barrel surface plate 12, and the step portion 5b supports, via anti-vibration units 11, the lens barrel surface plate 12.

The flange portion 10 is provided with a Z interferometer 45a and, as illustrated in FIG. 6, a corner cube 85 is provided on the top surface of the substrate stage PST so as to face the Z interferometer 45a. By receiving a light reflected from the corner cube 85, the Z interferometer 45a detects the information on the Z-direction position of the substrate stage PST separated from the projection optical system PL. The control unit CONT controls the posture of a substrate holder PH, based on the detection result of the Z interferometer 45a and the output of a focus sensor (not shown) for detecting the Z-direction position and posture of the photosensitive substrate P and the projection optical system PL.

Also, a plurality of Z interferometers 45b are provided on the bottom surface of the lens barrel surface plate 12. The details of these interferometers 45b will be described later.

The stage apparatus 2 includes a substrate stage PST serving as a movable body; a substrate surface plate 4 for supporting the substrate stage PST such that the substrate stage PST can move freely in two-dimensional directions according to an XY plane; an X guide stage 35 for supporting in a freely-movable manner the substrate stage PST while guiding in the X-axis direction; an X linear motor 40 provided on the X guide stage 35 for moving the substrate stage PST in the X-axis direction; and a pair of Y linear motors 30 for moving the X guide stage 35 in a Y-axis direction.

The substrate stage PST includes a substrate holder PH for vacuum-suctioning and holding the photosensitive substrate P such as a wafer or the like. The photosensitive substrate P is supported on the substrate stage PST through the substrate holder PH. Also, a plurality of air bearings 37, i.e., non-contact bearings, are provided at the bottom surface of the substrate stage PST. By these air bearings 37, the substrate stage PST is supported on the substrate surface plate 4 in a non-contacting manner by the air bearings 37. Further, the substrate surface plate 4 is supported substantially horizontally over the base plate 6 through the anti-vibration units 13 which are anti-vibration apparatus of the present invention.

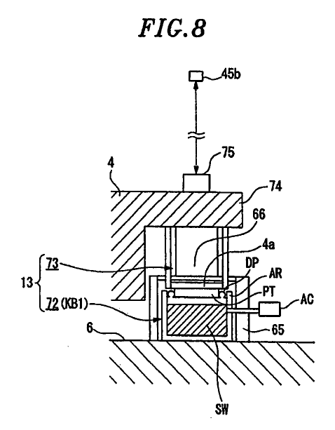

A mover 34a of an X trim motor 34 is attached at the plus X side of the X guide stage 35 (see FIG. 7). Further the stator (not shown) of the X trim motor 34 is provided on the reaction frame 5. Therefore, the reaction force acting at the time of driving the substrate stage PST in the X-axis direction is transmitted to the base plate 6 through the X trim motor 34 and the reaction frame 5.

FIG. 7 is a schematic perspective view of the stage apparatus 2 having the substrate stage PST.

As shown in FIG. 7, the stage apparatus 2 includes an X guide stage 35 elongated along the X-axis direction; an X linear motor 40 for moving the substrate stage PST in the X-axis direction with a predetermined stroke under the guidance of the X guide stage 35; and a pair of Y linear motors 30 provided at the opposite longitudinal ends of the X guide stage 35 for moving the X guide stage 35 along with the substrate stage PST in the Y-axis direction.

Each of the Y linear motors 30 includes a mover 32, i.e., a moving body formed with a magnet unit provided on each opposite longitudinal end of the X guide stage 35, and a stator 31 formed with a coil unit provided in a corresponding relationship with the mover 32. Here, the stator 31 is provided on a support portion 36 protruding from and installed at the base plate 6 (see FIG. 6). Further in FIG. 6, the stator 31 and the mover 32 are depicted in a simplified manner. The stator 31 and the mover 32 constitute the moving magnet type linear motors 30. The mover 32 is driven by the electromagnetic interaction between itself and the stator 31, thereby moving the X guide stage 35 in the Y-axis direction. Also, the X guide stage 35 is adapted to be rotatable in a θZ-direction by controlling the operation of the pair of Y linear motors 30. Accordingly, the substrate stage PST and the X guide stage 35 are made to be movable substantially as a whole in the Y-axis direction and the θZ-direction by means of the Y linear motors 30.

The X linear motor 40 includes a stator 41 formed with a coil unit provided on the X guide stage 35 to extend in the X-axis direction and a mover 42 formed with a magnet unit affixed to the substrate stage PST in a corresponding relationship with the stator 41. The stator 41 and the mover 42 constitute the moving magnet type linear motor 40. The mover 42 is driven by the electromagnetic interaction between itself and the stator 41, thereby displacing the substrate stage PST in the X-axis direction. Here, the substrate stage PST is supported in a non-contacting manner from the X guide stage 35 by a magnetic guide which maintains a predetermined gap in the Z-axis direction, wherein the magnetic guide formed with a magnet and an actuator. The substrate stage PST is moved in the X-axis direction by the X linear motor 40 while being supported in a non-contacting manner on the X guide stage 35. In addition, the non-contact support may be realized by employing an air guide instead of the magnetic guide.

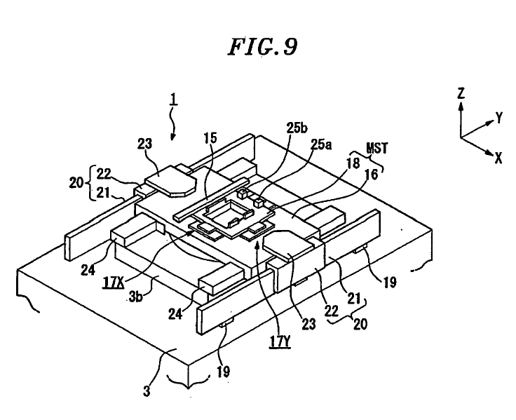

As shown in FIG. 8, the anti-vibration unit 13 includes an air mount (support device) 72 and a voice coil motor (drive device) 73 which are arranged in series along the Z-axis direction between a bracket portion 74, horizontally protruding from an end of the substrate surface plate 4, and the base plate 6.

Also, in FIG. 6, the anti-vibration unit 13 is illustrated in a simplified manner.

The air mount 72 is filled with an air (gaseous substance) of a predetermined pressure and is to support the substrate surface plate 4 which serves as a target anti-vibration object, in the Z-axis direction by use of (the pressure of) the air. The air mount 72 includes an air chamber AR mounted on the base plate 6; a piston PT for supporting the bracket portion 74 (substrate surface plate 4) in the Z-axis direction through a cradle 4a suspended from the bracket portion 74 of the substrate surface plate 4; a diaphragm DP covering the air chamber AR and supporting the piston PT in a way that the piston PT moves freely in the Z-axis direction; and a pneumatic pressure regulating device AC for controlling the quantity of the air supplied to the air chamber AR and regulating the pneumatic pressure under the control of the control unit CONT. The pneumatic spring apparatus KB1 shown in FIG. 1 is employed as the air mount 72 in this embodiment, and the inside of the air chamber AR is filled with the steel wool SW.

The voice coil motor 73 serves to drive the substrate surface plate 4 (bracket portion 74) in the Z-axis direction with electromagnetic force. The voice coil motor 73 is formed with a stator 65 provided on the base plate 6 so as to enclose the air chamber AR and a mover 66 provided in contact with the bracket portion 74 so as to be driven in the Z-axis direction with respect to the stator 65.

Also, on the bracket portion 74 of the substrate surface plate 4, there is installed a corner cube 75 that faces the Z interferometer 45b mentioned above and reflects a detection light irradiated from the Z interferometer 45b. The Z interferometer 45b receives the light reflected from the corner cube 75 to thereby acquire the position information (related to the Z-axis direction) of the surface of the substrate surface plate 4 in the Z-axis direction. The Z interferometer 45b and the corner cube 75 constitute a measuring device 76.

As shown in FIG. 7, the bracket portion 74, the corner cube 75 and the anti-vibration unit 13 are arranged in group at three points, i.e., almost at the center along the X-axis direction on the minus Y side of the substrate surface plate 4 and at the opposite ends along the X-axis direction on the plus Y side of the substrate surface plate 4 (However, the anti-vibration units 13 are not shown in FIG. 7). The position information related to the Z-axis direction of the substrate surface plate 4 acquired at the respective points is outputted to the control unit CONT. Based on the position information related to the Z-axis direction of the substrate surface plate 4, the control unit CONT calculates a plane and controls the operation of the anti-vibration units 13 (the air mounts 72 and the voice coil motors 73) based on the calculation result. A detection device 78 (see FIG. 6) that detects the distance between the substrate surface plate 4 and the base plate 6 is provided on the substrate surface plate 4 adjacent to each anti-vibration unit 13. The detection result of the detection device 78 is outputted to the control unit CONT.

Referring back to FIG. 6, an X-axis moving mirror 51 extending in the Y-axis direction is provided at the edge of the substrate stage PST on the minus X side, and a laser interferometer 50 is provided at a position facing the X-axis moving mirror 51. The laser interferometer 50 irradiates a laser beam (detection light) toward each of the specular surface of the X-axis moving mirror 51 and a reference mirror 52 provided at the bottom end of the lens barrel of the projection optical system PL and then measures the relative displacement of the X-axis moving mirror 51 and the reference mirror 52 based on the interference of the reflected light and the incident light, whereby the position of the substrate stage PST and hence the photosensitive substrate P in the X-axis direction are detected with a predetermined resolving power on a real time basis. In an identical manner, a Y-axis moving mirror 53 (not shown in FIG. 6, see FIG. 7) extending in the X-axis direction is provided at the edge of the substrate stage PST on the plus Y side and a Y laser interferometer (not shown) is provided in a position facing the Y-axis moving mirror 53. The Y laser interferometer irradiates a laser beam toward each of the specular surface of the Y-axis moving mirror 53 and a reference mirror (not shown) provided at the bottom end of the lens barrel of the projection optical system PL and then measures the relative displacement of the Y-axis moving mirror 53 and the reference mirror based on the interference of the reflected light and the incident light, whereby the position of the substrate stage PST and hence the photosensitive substrate P in the Y-axis direction are detected with a predetermined resolving power and on a real time basis. The detection results of the laser interferometers are outputted to the control unit CONT which in turn controls the position (and speed) of the substrate stage PST through the linear motors 30 and 40, based on the detection results of the laser interferometers.

The illumination optical system IL includes a mirror, a variable beam attenuator, a beam shaping optical system, an optical integrator, a beam condensing optical system, a vibrating mirror, an illumination system aperture stop plate, a beam splitter, a relay lens system, a blind unit (setting device) and the like, which are arranged in a predetermined positional relationship with one another, and it is supported by a support column 7 fixedly mounted on the top surface of the reaction frame 5. The blind unit includes a fixed blind having an opening of a given shape for defining an illumination region on the reticle R and a movable blind for further restricting, by use of a movable blade, the illumination region on the mask M defined by the fixed reticle blind, at the beginning and end of scanning exposure, to avoid any exposure of unnecessary parts.

Examples of the exposure light EL issued from the illumination optical system IL include deep ultraviolet lights of an ultraviolet emission line (g-line, h-line or i-line) generated by a mercury lamp, a KrF excimer laser beam with a wavelength of 248 nm and the like, and vacuum ultraviolet lights of an ArF excimer laser beam with a wavelength of 193 nm, a F₂ laser beam with a wavelength of 157 nm and the like.

Next, the mask surface plate 3 of the stage apparatus 1 is substantially horizontally supported at its corners on the step portion 5a of the reaction frame 5 through anti-vibration units 8 and is provided at its center with an opening 3a through which a pattern image of the mask M passes. Since the anti-vibration units 8 have the same configuration as that of the anti-vibration units 13, description thereon will be omitted.

A mask stage MST is provided on the mask surface plate 3 and has, at its center, an opening K aligned with the opening 3a of the mask surface plate 3 so as to allow the pattern image of the mask M to pass therethrough. A plurality of air bearings 9, i.e., non-contact bearings, are provided on the bottom surface of the mask stage MST, and the mask stage MST are floatingly supported by the air bearings 9 with a predetermined clearance on the mask surface plate 3.

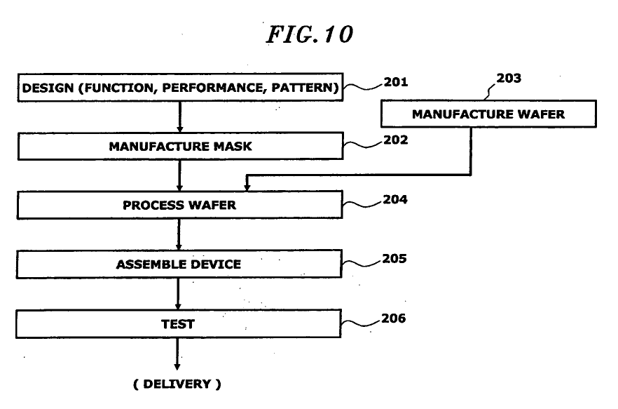

FIG. 9 is a schematic perspective view of the stage apparatus 1 having the mask stage MST.

As illustrated in FIG. 9, the stage apparatus 1 (mask stage MST) includes a mask coarse movement stage 16 provided on the mask surface plate 3; a mask fine movement stage 18 provided on the mask coarse movement stage 16; a pair of Y linear motors 20 and 20 for moving the coarse movement stage 16 on the mask surface plate 3 in the Y-axis direction with a predetermined stroke; a pair of Y guide members 24 and 24 provided on the top surface of a top-side protrusion 3b at the center portion of the mask surface plate 3 for guiding the coarse movement stage 16 in the Y-axis direction; and a pair of X voice coil motors 17X and a pair of Y voice coil motors 17Y for moving the fine movement stage 18 slightly on the coarse movement stage 16 in the X-axis, Y-axis and θZ-directions. In FIG. 6, the coarse movement stage 16 and the fine movement stage 18 are also illustrated as a single stage in a simplified manner.

Each of the Y linear motors 20 includes a pair of stator 21 and mover 22, wherein the stator is formed with a coil unit (armature unit) extending in the Y-axis direction on the mask surface plate 3 and the mover 22 is provided in a corresponding relationship with the stator 21 and formed with a magnet unit fixedly secured to the coarse movement stage 16 through a connecting member 23. The stator 21 and the mover 22 constitute the moving magnet type linear motor 20. The mover 22 is driven by the electromagnetic interaction between itself and the stator 21, thereby displacing the coarse movement stage 16 (mask stage MST) in the Y-axis direction. The stator 21 is floatingly supported on the mask surface plate 3 by a plurality of air bearings 19, i.e., non-contact bearings. Accordingly, under the law of conservation of momentum, the stator 21 is moved in a minus Y direction as the coarse movement stage 16 moves in a plus Y direction. Such movement of the stator 21 acts to counterbalance the reaction force created by the movement of the coarse movement stage 16 and also to prevent the change of the center position. Also, the stator 21 may be provided on the reaction frame 5 instead of the mask surface plate 3. In case where the stator 21 is provided on the reaction frame 5, the air bearings 19 may be removed and the stator 21 may be fixedly secured to the reaction frame 5 such that the reaction force exerted on the stator 21 by the movement of the coarse movement stage 16 can be absorbed through the reaction frame 5.

Each of the Y guide members 24 is to guide the coarse movement stage 16 moving in the Y-axis direction and is fixed so as to extend in the Y-axis direction on the top surface of the top-side protrusion 3b at the center portion of the mask surface plate 3. Further, air bearings, i.e., non-contact bearings (not shown) are provided between the coarse movement stage 16 and the Y guide members 24, and the coarse movement stage 16 is supported with respect to the Y guide members 24 in a non-contacting manner.

The fine movement stage 18 serves to absorb and hold the mask M via a vacuum chuck (not shown). A pair of Y-axis moving mirrors 25a and 25b formed with corner cubes are fixed to the end portion on the plus Y side of the fine movement stage 18, and an X-axis moving mirror formed with a planar mirror extending in the Y-axis direction is fixed to the end portion on the minus X side of the fine movement stage 18. Further, three laser interferometers (all are not shown) for irradiating distance measuring beams toward the moving mirrors 25a, 25b and 15 are provided, thereby measuring the distance between each mirror. By doing so, the X-axis, Y-axis and θZ-direction positions of the mask stage MST are detected with a high accuracy. Based on the results of measurement by the laser interferometers, the control unit CONT drives the respective motors, including the Y linear motors 20, the X voice coil motor 17X and the Y voice coil motor 17Y, to thereby control the position (and/or the speed) of the mask M (mask stage MST) supported on the fine movement stage 18.

Referring back to FIG. 6, the pattern image of the mask M that has passed the openings K and 3a is incident upon the projection optical system PL. The projection optical system PL is formed with a plurality of optical elements which in turn are supported by a lens barrel. The projection optical system PL is a reduction system that has a magnifying power of, e.g., 1/4 or 1/5. Alternatively, the projection optical system PL may be any one of an isometric system or a magnification system.

Three laser interferometers 45b are attached to the bottom surface of the lens barrel surface plate 12 in an opposing relationship with the corner cubes 75 mentioned above and serve as detection devices for detecting the relative position in the Z-axis direction with respect to the substrate surface plate 4 (Two of the laser interferometers 45b are representatively indicated in FIG. 6). Thus, each of three different Z positions of the substrate surface plate 4 are measured, respectively, with respect to the lens barrel surface plate 12 by means of the three laser interferometers 45b.

In the projection optical system PL, the flange portion 10 is coupled to the lens barrel surface plate 12 which in turn is substantially horizontally supported by anti-vibration units 11 on the step portion 5b of the reaction frame 5. The anti-vibration units 11 are of the same configuration as that of the anti-vibration units 13 and are formed with an air mount 26 and a voice coil motor 27 arranged in series.

Next, description will be given to the operation of the stage apparatus 2 of the exposure apparatus EX configured as above. When moving the substrate stage PST is moved in the Y-axis direction, the mover 32 of the Y linear motor 30 moves along the stator 31. Also, when moving the substrate stage PST in the X-axis direction, the mover 42 of the X linear motor 40 moves along the stator 41 (X guide stage 35).

At this moment, the control unit CONT controls the air mounts 72 and the voice coil motors 73 in such a manner that a counter force for canceling the influence caused by the change of center at the time of movement of the substrate stage PST is generated through a feedforward control of the anti-vibration units 13. In case where a minute magnitude of vibration is left in the six-degree-of-freedom directions of the substrate surface plate 4 due to the non-zero friction between the substrate stage PST and the substrate surface plate 4, a feedback control of the air mounts 72 and the voice coil motors 73 is performed to avoid the residual vibration.

More specifically, when the weight to be borne by the anti-vibration unit 13 is increased, the air of a predetermined pressure (e.g., 10 kPa) is filled into the air chamber AR by the pneumatic pressure regulating device AC of the air mount 72. This makes it possible to increase the support force required in supporting the bracket portion 74 of the substrate surface plate 4 through the piston PT and the cradle 4a.

In case where the increased weight cannot be sufficiently supported by the support force of the air mount 72, the voice coil motor 73 is driven to apply a thrust force to the bracket portion 74 of the substrate surface plate 4, thereby compensating for the deficient support force. In this process, the control unit CONT finds a plane which is defined by the Z-axis direction positions on the surface of the substrate surface plate 4 measured at three points by the Z-axis interferometers 45b, and controls the operation of the air mounts 72 and the voice coil motors 73 based on the plane thus found.

The residual vibration of the substrate surface plate 4 is actively damped by driving, based on the detection results of a vibration sensor group, the air mounts 72 and the voice coil motors 73 in the same manner applied at the time of center change. Thus, the minute vibration transmitted to the substrate surface plate 4 is insulated to a micro G level wherein the G denotes the acceleration of gravity. If the pressure in the air mount 72 is to be lowered due to a decrease in the weight to be borne by the anti-vibration unit 13, it is preferable that the air is evacuated from the internal space by the pneumatic pressure regulating device AC. In this way, the Z-axis direction position and posture of the substrate surface plate 4 (i.e., the photosensitive substrate P) is maintained in a desired condition by accurately measuring a variation of the substrate surface plate 4 and driving the air mount 72 and the voice coil motor 73 with a thrust force corresponding to the variation.

Continuously, description will be given to the exposure operation in the exposure apparatus EX configured as above.

Preparatory operations such as reticle alignment, base line measurement and the like are carried out through the use of a reticle microscope (not shown), an off-axis alignment sensor (not shown) and so forth. Then, the task of fine alignment (enhanced global alignment) of the photosensitive substrate P is completed using an alignment sensor, thereby finding arrangement coordinates of a plurality of shot regions on the photosensitive substrate P. Based on the alignment result and while monitoring the measured values of the laser interferometer 50, the linear motors 30 and 40 are controlled to displace the substrate stage PST into a scan start-up position in which the photosensitive substrate P is subjected to a first-shot exposure. Further, the mask stage MST and the substrate stage PST are scanned in the Y-axis direction through the operation of the linear motors 20 and 30. Once the stages MST and PST reach a target scan speed for each, a pattern region of the mask M is illuminated by an exposure illumination light which was set by the operation of the blind unit, thus commencing the scan exposure.

During the course of scan exposure, the mask stage MST and the substrate stage PST are synchronously controlled by means of the linear motors 20 and 30 in such a manner that the Y-direction moving speed of the mask stage MST and the Y-direction moving speed of the substrate stage PST are kept at a speed ratio corresponding to the projection magnifying power (1/5 or 1/4) of the projection optical system PL. In the event that the variation of the substrate surface plate 4 occurs in the process of moving the substrate stage PST, the anti-vibration units 13 are controlled to compensate for the variation of the substrate surface plate 4, as described above, to make it possible to bring the surface position of the photosensitive substrate P to the focal position of the projection optical system PL.

Further, the residual vibration of the lens barrel surface plate 12 is actively damped by controlling the air mount 26 and the voice coil motor 27 in the same manner as applied at the time of center change caused by the stage movement. Thus, the minute vibration transmitted to the lens barrel surface plate 25 (projection optical system PL) through the bottom support frame 5d is insulated to a micro G level wherein the G denotes the acceleration of gravity.

Different pattern regions of the mask M are illuminated one after another by the illumination light, eventually completing the illumination tasks for the entirety of the pattern regions. By doing so, the first-shot scan exposure of the photosensitive substrate P is completed. From this, the patterns of the mask M are reduce-transferred to the first-shot region on the photosensitive substrate P via the projection optical system PL.

As set forth above, in this embodiment, the temperature change caused by the change of internal volume of the air chamber AR at the time of operating the air mount 72 is suppressed by the instantaneous heat exchange with the steel wool SW, thereby making it possible to suppress the pressure change arising from the temperature change (heat) This reduces the polytropic index for the air mount 72 and hence reduces the spring constant, thereby improving the vibration transmission rate. As a consequence, effectively damping the vibration of the substrate surface plate 4 becomes possible, which in turn improves the pattern transfer accuracy.

While preferred embodiments of the invention have been described with reference to the accompanying drawings, it should be understood without saying that the present invention is not limited to such embodiments. It will be apparent to those skilled in the art that various changes and modification may be made within the spirit and scope of the invention as defined in the claims and further that such changes and modification fall within the technical scope of the present invention.

For example, although FIGS. 6 and 8 show configurations employing the pneumatic spring apparatus KB1 of the first embodiment described with reference to FIG. 1, an alternative configuration employing one of the pneumatic spring apparatuses of the second to fifth embodiments can be made which, however, is not limited by such. The pneumatic spring apparatuses described in connection with the first to fifth embodiments may be properly employed in combination.

Furthermore, although the stage apparatus of the present invention is applied to the substrate stage in the foregoing embodiments, it is not limited thereto, but may alternatively be applied to the mask stage. Moreover, the pneumatic spring apparatuses of the foregoing embodiments may be applied to the air mounts 26 supporting the lens barrel surface plate 12.

Further, examples of the photosensitive substrate P usable in the respective embodiments include not only a semiconductor wafer for the manufacture of a semiconductor device but also a glass substrate for display devices, a ceramic wafer for thin film magnetic heads and a raw substrate (synthetic quartz or silicon wafer) of a mask or reticle used in exposure apparatuses.

Examples of the exposure apparatus EX usable in the present invention include not only a step-and-scan type scanning exposure apparatus (“scanning stepper”) by which a mask M and a substrate P are synchronously displaced to subject the patterns of the mask M to scanning exposure, but also a step-and-repeat type projection exposure apparatus (“stepper”) by which the patterns of a mask M are subjected to one-shot exposure, with the mask M and the substrate P kept stationary, and then the substrate P is moved step by step. The present invention may also be applied to a step-and-stitch type exposure apparatus by which at least two patterns are partially re-transferred on the substrate P.

Further, the present invention may also be applied to twin stage type exposure apparatuses disclosed in Japanese Patent Laid-open Application Nos. H10-163099, H10-214783, 2000-505958 or the like.

As for the exposure apparatus EX, it is not limited to an exposure apparatus for the manufacture of a semiconductor device by which the patterns of a semiconductor device are exposed on a substrate P. Instead, the present invention may be widely applied to other kinds of exposure apparatuses, e.g., an exposure apparatus for the manufacture of a liquid crystal display elements or the manufacture of a display and an exposure apparatus for the manufacture of a thin film magnetic head, an image taking device (charge coupled device) or a reticle (mask).

In case where a linear motor (see U.S. Pat. No. 5,623,853 or U.S. Pat. No. 5,528,118) is employed in the substrate stage PST or the mask stage MST, either an air floating type linear motor with air bearings or a magnetic floating type linear motor which takes advantage of the Lorentz force or a reactance force may be employed. Further, each of the stages PST and MST may be a type which moves along a guide or a guideless type which is not provided with a guide.

A planar motor that electromagnetically drives the respective stages PST and MST by opposingly arranging a magnet unit with two-dimensionally disposed magnets and an armature unit with two-dimensionally disposed coils may be used as a drive mechanism of the respective stages PST and MST. In this case, one of the magnet unit and the armature unit may be attached to the stages PST and MST and the other of the magnet unit and the armature unit may be provided on the surface along which the stages PST and MST move.

The reaction force generated by the movement of the substrate stage PST may be allowed to be mechanically alleviated to the floor (ground) through a frame member without being transmitted to the projection optical system PL, as disclosed in Japanese Patent Laid-open Application No. H8-166475 (U.S. Pat. No. 5,874,820).

The reaction force generated by the movement of the mask stage MST may be allowed to be mechanically alleviated to the floor (ground) through a frame member without being transmitted to the projection optical system PL, as disclosed in Japanese Patent Laid-open Application No. H8-330224 (U.S. Pat. No. 5,874,820). The reaction force may also be treated using the law of conservation of momentum, as disclosed in Japanese Patent Laid-open Application No. H8-63231 (U.S. Pat. No. 6,255,796).

The exposure apparatus EX of embodiments in the subject application is manufactured by assembling various sub-systems including individual elements recited in the claims of the subject application that could be within the range of the claims, to maintain a prescribed degree of mechanical precision, electrical precision and optical precision. In an effort to secure the degree of the precisions, calibration for achieving optical precision for various optical systems, calibration for achieving mechanical precision for various mechanical systems and calibration for achieving electrical precision for various electrical systems are performed before and after the combining operation. The process of assembling the various sub-systems into the exposure apparatus includes mechanical coupling, wire connection of electric circuits, pipeline connection of pneumatic circuits and the like. It is not even worth to mention that each of the sub-systems is pre-assembled prior to be assembled into the exposure apparatus. Once the process of assembling the various sub-systems into the exposure apparatus is completed, overall calibration is carried out to assure various types of precisions for the exposure apparatus as a whole. It is preferred that the manufacture of the exposure apparatus is performed in a clean room whose temperature, cleanliness and the like are controlled.

As illustrated in FIG. 10, a micro device such as a semiconductor device or the like is manufactured through a step 201 of designing the function and performance of the micro device, a step 202 of manufacturing a mask (reticle) based on the designing step, a step 203 of manufacturing a wafer as a base material of the micro device, a step 204 of exposing the patterns of the mask on the wafer by means of the exposure apparatus EX of the above-described embodiment, a step 205 of assembling the micro device (including a dicing step, a bonding step and a packaging step), a step 206 of testing the micro device and the like.

1. A pneumatic spring apparatus having a gas chamber filled with a gaseous substance of a predetermined pressure, comprising a regulating device provided in the gas chamber for regulating a temperature change produced according to a volume change of the gas chamber.

2. The pneumatic spring apparatus of claim 1, wherein the regulating device is a solid or a liquid exhibiting a greater specific heat or heat transfer rate than the gaseous substance.

3. The pneumatic spring apparatus of claim 1 or 2, wherein the regulating device is fiber-shaped steel.

4. The pneumatic spring apparatus of claim 1 or 2, wherein the regulating device is adapted to make a polytropic index for a dynamic spring constant smaller than a polytropic index of the air.

5. The pneumatic spring apparatus of claim 1 or 2, wherein the regulating device includes a gas formed of a mixture of saturated vapor and liquid filled in the gas chamber in a gas liquid mixed phase condition.

6. The pneumatic spring apparatus of claim 1 or 2, wherein the regulating device is adapted to allow a volume of the gas chamber to be changed nearly isothermally.

7. The pneumatic spring apparatus of claim 1 or 2, further comprising a stirring device for stirring the gaseous substance in the gas chamber.

8. An anti-vibration apparatus comprising:
a support device for supporting a target anti-vibration object with a gaseous substance of a predetermined pressure; and
a drive device for driving the target anti-vibration object,
wherein the pneumatic spring apparatus of claim 1 or 2 is employed as the support device.

9. A stage apparatus in which a movable body is moved on a surface plate, wherein the surface plate is supported by the anti-vibration apparatus of claim 8.

10. An exposure apparatus for use in exposing patterns of a mask held on a mask stage onto a photosensitive substrate held on a substrate stage through a projection optical system, wherein at least one of the mask stage, the projection optical system and the substrate stage is supported by the anti-vibration apparatus of claim 8.

11. An anti-vibration method comprising the steps of:
filling a gaseous substance of a predetermined pressure into a gas chamber; and
regulating a temperature change produced according to a volume change of the gas chamber.

12. The anti-vibration method of claim 11, wherein a solid or a liquid exhibiting a greater specific heat or heat transfer rate than the gaseous substance is filled in the gas chamber.

13. The anti-vibration method of claim 11 or 12, wherein fiber-shaped steel is filled in the gas chamber.

14. The anti-vibration method of claim 11 or 12, wherein a polytropic index for a dynamic spring constant is made smaller than a polytropic index of the air.

15. The anti-vibration method of claim 11 or 12, wherein a gas formed of a mixture of saturated vapor and liquid is filled in the gas chamber in a gas liquid mixed phase condition.

16. The anti-vibration method of claim 11 or 12, wherein a volume of the gas chamber is changed nearly isothermally.

17. The anti-vibration method of claim 11 or 12, wherein the gaseous substance in the gas chamber is stirred.
